(19) United States
(12) Patent Application Publication
(10) Pub. No.: US 2026/0146527 A1
(43) Pub. Date: May 28, 2026

(54) DATA-DRIVEN DEPTH UNCERTAINTY ESTIMATION FOR DRILLING OPERATIONS

(71) Applicant: CHEVRON U.S.A. INC., San Ramon, CA (US)

(72) Inventors: Huafeng LIU, Bellaire, TX (US); Jinsong CHEN, Fulshear, TX (US)

(21) Appl. No.: 19/054,470

(22) Filed: Feb. 14, 2025

Related U.S. Application Data
(63) Continuation-in-part of application No. 18/962,385, filed on Nov. 27, 2024, now abandoned.

(51) Int. Cl. E21B 47/04; G06F 30/27

(52) U.S. Cl. CPC E21B 47/04; G06F 30/27; E21B 2200/20; E21B 2200/22

(57) ABSTRACT

Systems and methods are directed to estimating depth uncertainty at a well location. The system can receive mistie data from a plurality of wells in a geographic region and determine a plurality of factors impacting depth uncertainty for each of the plurality of wells based on the mistie data. One or more machine learning models can be trained with the plurality of factors to calculate depth uncertainty for each of the plurality of wells. For a new well in the geographic region, the system can apply the trained one or more machine learning models to generate one or more graphical representations of depth uncertainty for the new well.

### CROSS-REFERENCE TO RELATED APPLICATION

This application is a continuation-in-part of and claims the benefit of U.S. application Ser. No. 18/962,385 filed Nov. 27, 2024, which is hereby incorporated herein by reference in its entirety.

### TECHNICAL FIELD

The present disclosure relates generally to hydrocarbon production, and in particular, some implementations may relate to characterizing subsurface features to estimate hydrocarbon production.

### DESCRIPTION OF RELATED ART

Subsurface depth uncertainty estimation plays an important role in the risk mitigation of hydrocarbon production and CO₂ storage. Depth uncertainty refers to the uncertainty in the target depths of subsurface features when using seismic data. Depth uncertainty, if ignored, can result in many costly mistakes associated with well planning and drilling. Depth uncertainty can affect different aspects of well planning such as casing design, hazard detection, and efficient drilling. In resource assessment, depth uncertainty also affects the estimated ultimate recovery (EUR) of the reservoir, which affects both drilling decisions and the size of facilities to be built for hydrocarbon production. Traditional depth uncertainty estimating systems have not been integrated into well planning systems and are limited to the surfaces of reservoir intervals. Due to the complexity of geological structures, and the limitations of seismic data, it can be challenging to fully determine depth uncertainty.

### BRIEF SUMMARY OF THE DISCLOSURE

According to various embodiments of the disclosed technology, a method for estimating depth uncertainty of formation tops in a well can include receiving mistie data for a plurality of wells in a geographic region. Mistie data can be referred to be the difference between prognosis depth and actual depth of formation tops from wells. In some embodiments, mistie data can be stored in a column-based data file. Auxiliary information available with the mistie values can include a three-dimensional location (x,y,z) of the sample point, formation top names, well drilling date, or any other relevant information. The system can determine a plurality of factors impacting depth uncertainty for each available well. In some embodiments, the factors can include total depth below mudlines, well types, seismic data types, number of wells in the geographic region, and/or distance from nearest wells. In some embodiments, the factors can be weighted equally, while in other embodiments, the factors can be treated differently based on how the one or more machine learning models are trained.

In some embodiments, the system can generate a numerical table describing the factors for each data point in the well or describing a summation for multiple wells. The system can train a machine learning model with the plurality of factors to calculate depth uncertainty for each well. In some embodiments, the machine learning model may comprise Generalized Additive Models (“GAM model”), which can be linear or nonlinear functions of the exploratory factors depending on training data. The system can apply the trained machine learning model to new wells to estimate depth uncertainty. In some embodiments, the estimates can include point or line plots for each well. In other embodiments, the estimates can include a heat map of depth uncertainty for a particular or multiple wells.

In accordance with another embodiment, a system for determining depth uncertainty can include a processor and a memory encoded with instructions. The instructions, when executed by the processor, can cause the processor to receive mistie data for a plurality of wells in a geographic region. The system can determine a plurality of factors impacting depth uncertainty for each well. In some embodiments, the factors can include total depth below mudline, well types, seismic data types, number of wells in the geographic region, and/or distance from nearest wells. The system can train machine learning models with multiple factors to calculate depth uncertainty for each well. In some embodiments, the system can generate a property surface with associated uncertainty along the reservoir surface.

In accordance with another embodiment, a non-transitory machine-readable storage medium can be encoded with instructions, which, when executed by a processor, can cause the processor to receive mistie data for a plurality of wells in a geographic region. The system can determine multiple factors impacting depth uncertainty for each well. In some embodiments, the factors can include total depth below mudline, well types, seismic data types, number of wells in the geographic region, and/or distance from nearest wells. The non-transitory machine-readable storage medium can be used to train one or more machine learning models with multiple factors to calculate depth uncertainty for each well. The non-transitory machine-readable storage medium can generate a table of numerical values for each factor and for each well illustrating depth uncertainty for each well.

Other features and aspects of the disclosed technology will become apparent from the following detailed description, taken in conjunction with the accompanying drawings, which illustrate, by way of example, the features in accordance with embodiments of the disclosed technology. The summary is not intended to limit the scope of any inventions described herein, which are defined solely by the claims attached hereto.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The present disclosure, in accordance with one or more various embodiments, is described in detail with reference to the following figures. The figures are provided for purposes of illustration only and merely depict typical or example embodiments.

FIG. 1 illustrates an example system in accordance with the embodiments described herein.

FIG. 2 illustrates a first representation of depth uncertainty estimations in accordance with one embodiment.

FIG. 3 illustrates a second graphical representation of depth uncertainty estimations in accordance with one embodiment.

FIG. 4 illustrates an example method in accordance with the embodiments described herein.

FIG. 5 is an example computing component that may be used to implement various features of embodiments described in the present disclosure.

The figures are not exhaustive and do not limit the present disclosure to the precise form disclosed.

### DETAILED DESCRIPTION

Traditional systems can apply data to estimate depth uncertainty in various ways. Some systems apply Monte Carlo methods to generate an ensemble of models based on a given reference model (including seismic velocity and anisotropic parameters) and seismic data by perturbation. Here, Monte Carlo methods refer to the use of simulated random numbers to estimate some probability distributions. The probability distributions may be generated by estimating the expected value by the use of many simulated samples. These functions apply physics by flattening the seismic traces obtained in a survey. These functions may be used to determine depth uncertainty at each location. While this method is effective under certain conditions, it does not consider non-seismic data (e.g. petrophysics data, geological constraints, model update based on mistie data from wells) and their impact on depth uncertainty. Accordingly, the resulting derived uncertainty bounds can be very large. Other systems apply 3D stochastic methods to generate velocity and anisotropy parameters in a vertical transverse isotropy (VTI) medium. These systems apply normal moveout (NMO) travel time and detectability criteria to guide model generations. These models can be constrained with 3D seismic data to further reduce depth uncertainty. These models work well when subsurface structures are relatively simple. However, in practice, many subsurface geological structures are complex, and reference models may be subject to unknown biases and interpretation uncertainties. These complexities can reduce the visual quality of the depth uncertainty estimation representations. In addition, traditional estimation systems have not been integrated into well planning systems and are limited to the surfaces of reservoir intervals. Accordingly, traditional systems are not applicable to well planning cases, nor do they have appropriately accuracy and speed for well planning.

Embodiments of the systems and methods disclosed herein leverage mistie data from a set of wells in one or more machine learning models to learn the relationship between subsurface features and misties from wellbores. Here, mistie data can be referred to be any data on the difference between estimated depth and the actual depth. Auxiliary factors available with mistie data can include location information, formation names, well drilling date, or any other relevant information. Relevant features considered in determining depth uncertainty can include total depth below mudlines, well types, seismic types, number of pre-existing wells in neighborhoods and/or distance away from nearest wells. The one or more models can be trained for one or more locations to produce accurate predictions of depth uncertainty. This system can be executed in a much shorter time than the approaches that rely on seismic-based data. In addition, the features used for depth uncertainty estimation in applications are either simple facts or can be directly derived from simple facts, hence, easy to retrieve and to be prepared for estimating depth uncertainty in well planning. The involved data also covers all formation tops where the prognosis depth and actual depth were recorded, so as to cover all well planning cases. The resulting estimation are much faster and have higher accuracy than traditional systems. Additionally, the systems and embodiments described herein are directed to an improved user interface for displaying and interacting with depth uncertainty estimations as provided above. As described above, traditional representations and displays may not be accurate in well planning cases. The technology described herein includes methods of obtaining more accurate depth uncertainty and displaying the information to the user, rather than using conventional methods to depth uncertainty. These systems recite a specific improvement over conventional systems, including an improved user interface for use in hydrocarbon drilling.

These systems and embodiments improve the efficiency of hydrocarbon drilling by providing more accurate predictions of depth uncertainty in a subsurface area of interest. This improved display allows for the presentation and consumption of information in a unique and necessary manner that enables personnel to immediately have the information they need accurately and quickly identify desired, target well designs or operate drilling machines. It also improves the confidence of driller operating the drilling bits and results in faster and safer drilling operations. This display also assists in characterizing subsurface features in the area of interest. The speed and ease of using this display greatly reduces the time it takes to analyze mistie data, which is already a lengthy process. Rather than providing a rough estimate of depth uncertainty, this display greatly improves accuracy of analyzing mistie data and provides personnel with immediate information on important subsurface features.

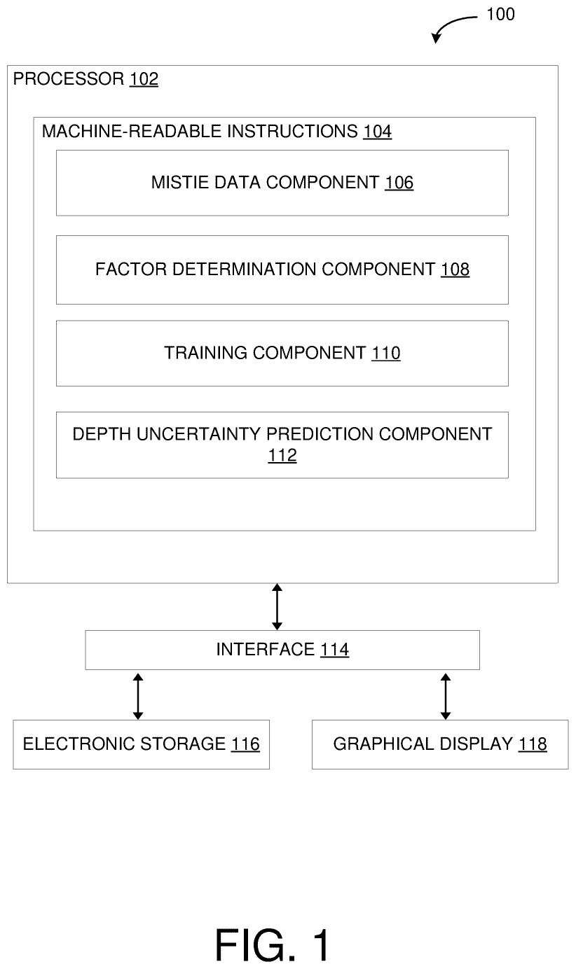

FIG. 1 illustrates an example system 100 incorporating the systems and methods described above. The electronic storage 116 may be configured to include an electronic storage medium that electronically stores information. The electronic storage 116 may store software algorithms, information determined by the processor 102, information received remotely, and/or other information that enables the system 100 to function properly. For example, electronic storage 116 may store information relating to seismic data, and/or other information. The electronic storage media of electronic storage 116 may be provided integrally (i.e., substantially non-removable) with one or more components of the system 100 and/or as removable storage that is connectable to one or more components of the system 100 via, for example, a port (e.g., a USB port, a Firewire port, etc.) or a drive (e.g., a disk drive, etc.). The electronic storage 116 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. Electronic storage 116 may be a separate component within system 100, or electronic storage 116 may be provided integrally with one or more other components of system 100 (e.g., processor 102). Although electronic storage 116 is shown in FIG. 1 as a single entity, this is for illustrative purposes only. In some implementations, electronic storage 116 may include a plurality of storage units. These storage units may be physically located within the same device, or electronic storage 116 may represent storage functionality of a plurality of devices operating in coordination.

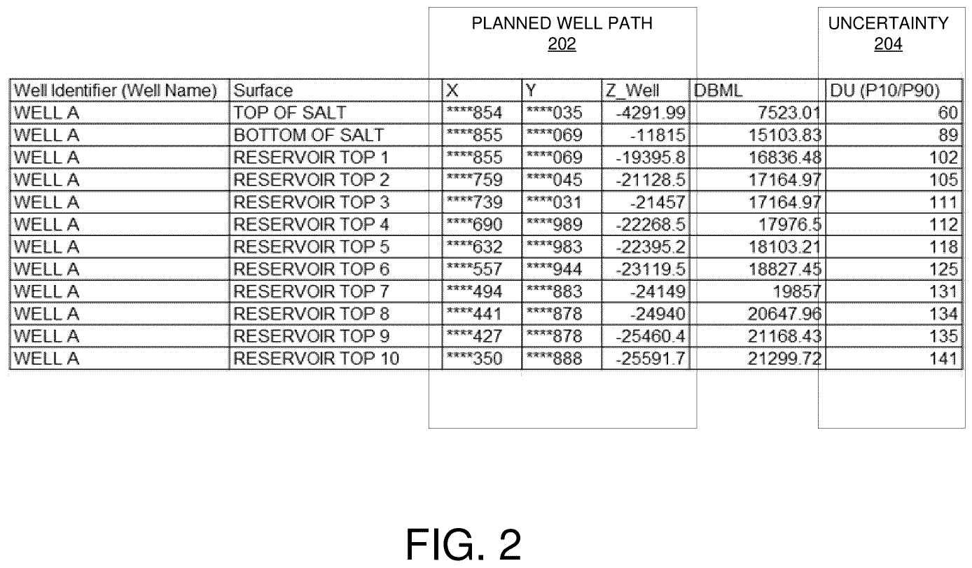

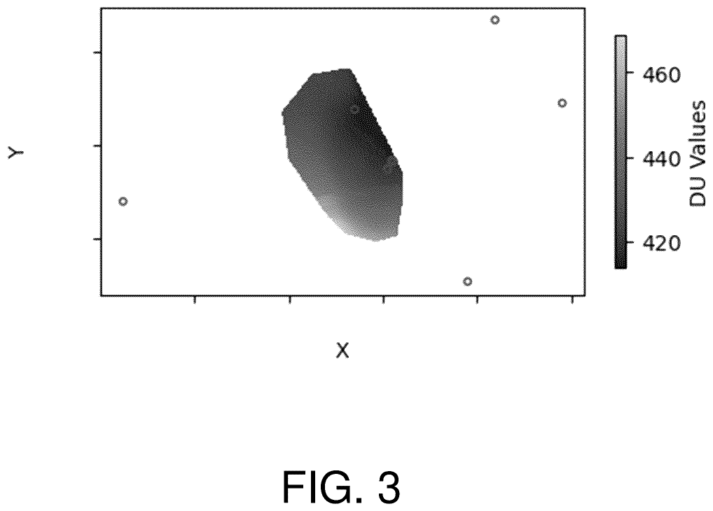

Graphical display 118 may refer to an electronic device that provides visual presentation of information. Graphical display 118 may include color displays and/or non-color displays. Graphical display 118 may be configured to visually present information in multiple ways. Graphical display 118 may present information using/within one or more graphical user interfaces. For example, graphical display 118 may present information relating to seismic data, seismic picks, and/or other information. Graphical display 118 may present information including, but not limited to, graphical representations of depth uncertainty as described below in FIGS. 2 and 3.

Processor 102 may be configured to provide information processing capabilities in the system 100. As such, processor 102 may include one or more of a digital processor, an analog processor, a digital circuit designed to process information, a central processing unit, a graphics processing unit, a microcontroller, an analog circuit designed to process information, a state machine, and/or other mechanisms for electronically processing information. Processor 102 may be configured to execute one or more machine-readable instructions 104 to facilitate seismic event picking. Machine-readable instructions 104 may include one or more computer program components. Machine-readable instructions 104 may include a mistie data component 106, factor determination component 108, a training component 110, a depth uncertainty component 112, a characterization component 114, and/or other computer program components.

It should be appreciated that although computer program components are illustrated in FIG. 1 as being co-located within a single processing unit, one or more of computer program components may be located remotely from the other computer program components. While computer program components are described as performing or being configured to perform operations, computer program components may include instructions which may program processor 102 and/or system 100 to perform the operation.

While computer program components are described herein as being implemented via processor 102 through machine-readable instructions 104, this is merely for ease of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented.

Referring again to machine-readable instructions 104, component 106 can be configured to accept any mistie data as input. In some embodiments, mistie data can be stored in a column-based data file. Auxiliary information available with the mistie values can include a 3-dimensional location (x,y,z) of the sample point, formation top names, dipping angles of formation tops, well drilling date, types of well, types of seismic data, seismic image quality, or any other relevant information.

Factor determination component 108 can be configured to identify factors impacting depth uncertainty for the well based on the mistie data. The factors can be related to total depth below mudline, well types, seismic data types, number of pre-existing wells in neighborhood and/or distance away from nearest wells. In some embodiments, well types can include exploration wells, appraisal wells, or development wells, where the well types signify the purpose or use for the well. Seismic data types can include, but are not limited to narrow azimuth data, wide azimuth data, full-azimuth data, ocean-bottom node data, or any other data identified by the type of seismic survey applied. In some embodiments, the system can generate a table of numerical values for each factor as applied to the mistie data. In some embodiments, these factors can be weighted equally. In other embodiments, a machine learning model can evaluate how the factors contribute to the depth uncertainty prediction and weight factors accordingly for future wells. In some embodiments, some or all of the above listed factors may be considered, depending on the mistie data or focus for the depth uncertainty evaluation. In some embodiments, the system can learn the relations between different factors and depth uncertainty based on historical mistie data from wells. The learned weights can be applied to determine depth uncertainty for future wells, given the factors from the future well.

Training component 110 can be configured to train one or more machine learning models to calculate depth uncertainty for one or more wells. In some embodiments, the machine learning models may comprise Generalized Additive Models (GAM), which can leverage the factors linearly or non-linearly based on the deterministic unknown smooth functions. GAM models can incorporate constraints to allow interpretable behavior of the model. For example, the model may recognize that the depth uncertainty may increase with an increased depth below mudline. In other cases, the model may recognize that the depth uncertainty may increase smoothly with an increased distance from existing wells. In some embodiments, the factors determined using factor determination component 108 can be incorporated into spline functions after normalization. Resulting depth uncertainty predictions can comprise summations of each spline function. In some embodiments, coefficients of the spline functions can include model parameters that are optimized during training.

Depth uncertainty prediction component 112 can be configured to generate a representation of depth uncertainty for new wells based on the trained models. In some embodiments, the representation can comprise point or line plots for each well. These plots can include a vertical axis for depth or formation names while the horizontal axis can correspond to predicted depth uncertainty. In some embodiments, depth uncertainty can be measured and displayed based on confidence intervals (CI). For example, 80% or 98% confidence intervals (CI) can be used, or ranges between 10% and 90% quantiles or between 1% and 99% quantiles. Here, 80% CI means predicting 80% of the time that the actual mistie will be inside the predicted range. In some embodiments, these confidence intervals can be represented using a heat map of the depth uncertainty values as applied to each geographic location or point for a well.

The description of the functionality provided by the different computer program components described herein is for illustrative purposes, and is not intended to be limiting, as any of computer program components may provide more or less functionality than is described. For example, one or more of computer program components may be eliminated, and some or all of its functionality may be provided by other computer program components. As another example, processor 102 may be configured to execute one or more additional computer program components that may perform some or all of the functionality attributed to one or more of computer program components described herein.

FIG. 2 illustrates example resulting depth uncertainty representations for different formation tops along a planned development well. In FIG. 2, DBML refers to the total depth below mudline. Surface refers to formation top names. Planned well path 202 can comprise (x,y,z) coordinates that can be input from well planning. Uncertainty 204 can be generated based on the factors and weights described above in FIG. 1. As described above, the estimates from traditional systems fail to capture the P10/P90 depth uncertainty variations in development wells and, therefore, cannot accurately represent the depth uncertainty. Similarly, traditional estimate fails to capture the depth uncertainty variation among different seismic type, number of existing wells nearby and distance away from nearest well. In contrast, the forementioned new method accounts for variation in these factors and, hence, more accurately represent the actual depth uncertainty. As described above, representations of depth uncertainty for a well can comprise point or line plots for each well. These plots can include a vertical axis for depth or formation names while the horizontal axis can correspond to predicted depth uncertainty.

FIG. 3 illustrates an example display of depth uncertainty values incorporated into a heat map along a reservoir surface. As illustrated in FIG. 3, this example display incorporates a two-dimensional representation of the reservoir based on (x,y) coordinates. The heat map can vary color shading based on the magnitude of the depth uncertainty values. The red circles represent well locations near this reservoir. The representations in FIGS. 2 and 3 provide results when the workflow given in FIG. 1 is applied to a particular well or a particular reservoir. As described above, these new estimates provide more accurate and reliable information for hydrocarbon explorations and production. Therefore, they can lead to significant cost reduction and improve risk managements.

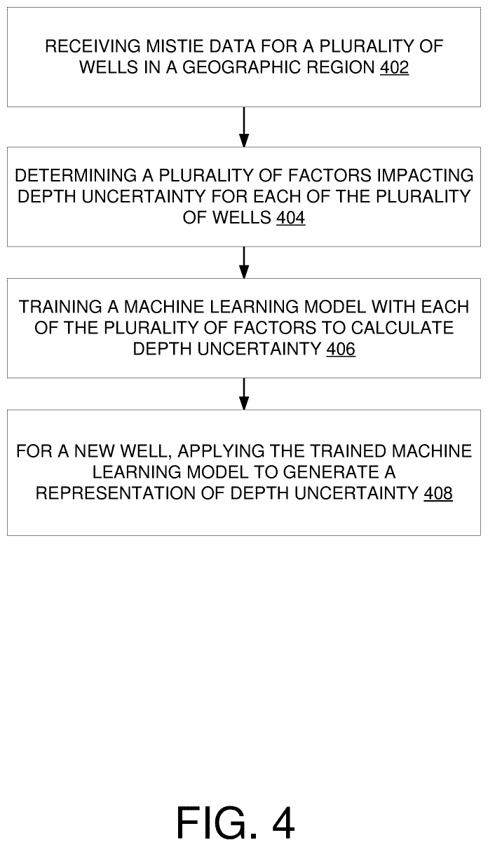

FIG. 4 illustrates an example method in accordance with the embodiments described above. At block 402, the system can receive mistie data for a plurality of wells in a geographic region. As described above, in some embodiments, mistie data can be stored in a column-based data file. Auxiliary information available with the mistie values can include a 3-dimensional (x,y,z) location of the sample point, formation top names, well drilling date, or any other relevant information. Mistie data can include information that can be used to calculate necessary factors such as well types, seismic types, number of wells in the geographic region distance from nearest wells, and/or total depth below mudline.

At block 404, the system can determine a plurality of factors impacting depth uncertainty for each of the plurality of wells. As described above, relevant factors can include key factors related to depth uncertainty based on characteristics of the well. In some embodiments, the factors can be weighted equally, while in other embodiments, the factors can be treated differently based on how a machine learning model is trained. As described above, in some embodiments, the system can generate a numerical table describing the factors for each data point in the well or describing a summation for multiple wells. An example table is illustrated below:

| | | Depth | | | |
|---|---|---|---|---|---|
| Well | | Below | | Data | Depth |
| Identifier | Distance | Mudline | Well Type | Type | Uncertainty |
| A | 100,000 | −10,000 | Exploration | WAZ | 700 |
| B | 30,000 | −15,000 | Exploration | FAZ | 400 |
| C | 10,000 | −20,000 | Development | OBN | 200 |

At block 406, the system can train one or more machine learning models with the plurality of factors to calculate depth uncertainty for each of the plurality of wells. As described above, in some embodiments, the one or more machine learning models may comprise a GAM model, which can be linear or nonlinear functions of the factors based on unknown smoothing functions. In some embodiments, the factors can be incorporated into spline functions after normalization. Resulting depth uncertainty predictions can comprise summations of spline functions. In some embodiments, coefficients of the spline functions can include model parameters that are optimized during training.

At block 408, the system can apply the trained machine learning models to a new well to generate a representation of depth uncertainty. As described above, the representation may include a numerical table as described regarding block 404. In some embodiments, the representation can include point or line plots for each well. In some embodiments, depth uncertainty can be measured and displayed based on confidence intervals. In other embodiments, the representation can include a heat map of depth uncertainty for a particular or multiple wells. The heat map can show confidence intervals as applied to each geographic location or point for a reservoir.

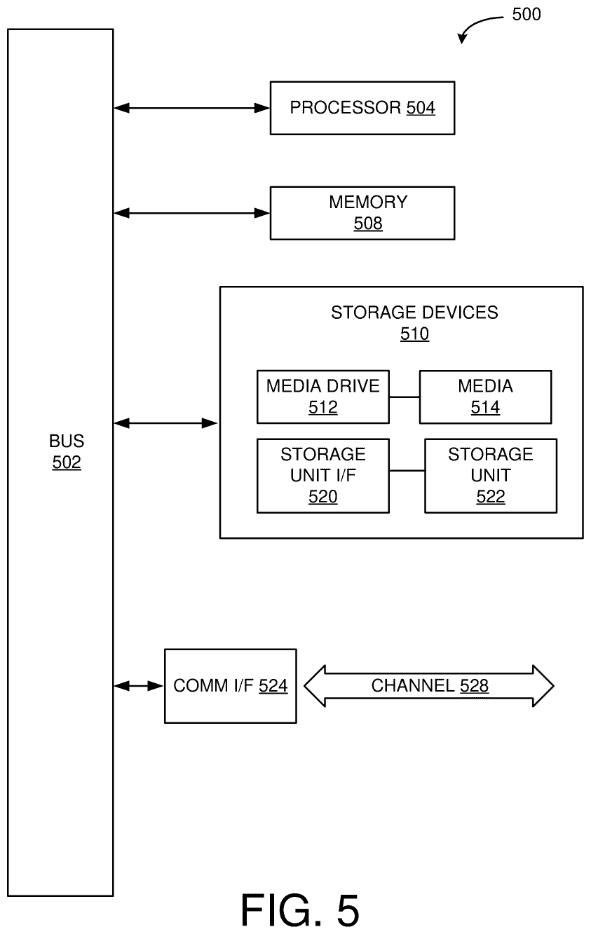

As used herein, the terms circuit and component might describe a given unit of functionality that can be performed in accordance with one or more embodiments of the present application. As used herein, a component might be implemented utilizing any form of hardware, software, or a combination thereof. For example, one or more processors, controllers, ASICs, PLAS, PALs, CPLDs, FPGAs, logical components, software routines or other mechanisms might be implemented to make up a component. Various components described herein may be implemented as discrete components or described functions and features can be shared in part or in total among one or more components. In other words, as would be apparent to one of ordinary skill in the art after reading this description, the various features and functionality described herein may be implemented in any given application. They can be implemented in one or more separate or shared components in various combinations and permutations. Although various features or functional elements may be individually described or claimed as separate components, it should be understood that these features/functionalities can be shared among one or more common software and hardware elements. Such a description shall not require or imply that separate hardware or software components are used to implement such features or functionality.

Where components are implemented in whole or in part using software, these software elements can be implemented to operate with a computing or processing component capable of carrying out the functionality described with respect thereto. One such example computing component is shown in FIG. 5. Various embodiments are described in terms of this example-computing component 500. After reading this description, it will become apparent to a person skilled in the relevant art how to implement the application using other computing components or architectures.

Referring now to FIG. 5, computing component 500 may represent, for example, computing or processing capabilities found within a self-adjusting display, desktop, laptop, notebook, and tablet computers. They may be found in hand-held computing devices (tablets, PDA's, smart phones, cell phones, palmtops, etc.). They may be found in workstations or other devices with displays, servers, or any other type of special-purpose or general-purpose computing devices as may be desirable or appropriate for a given application or environment. Computing component 500 might also represent computing capabilities embedded within or otherwise available to a given device. For example, a computing component might be found in other electronic devices such as, for example, portable computing devices, and other electronic devices that might include some form of processing capability.

Computing component 500 might include, for example, one or more processors, controllers, control components, or other processing devices. Processor 504 might be implemented using a general-purpose or special-purpose processing engine such as, for example, a microprocessor, controller, or other control logic. Processor 504 may be connected to a bus 502. However, any communication medium can be used to facilitate interaction with other components of computing component 500 or to communicate externally.

Computing component 500 might also include one or more memory components, simply referred to herein as main memory 508. For example, random access memory (RAM) or other dynamic memory, might be used for storing information and instructions to be executed by processor 504. Main memory 508 might also be used for storing temporary variables or other intermediate information during execution of instructions to be executed by processor 504. Computing component 500 might likewise include a read only memory (“ROM”) or other static storage device coupled to bus 502 for storing static information and instructions for processor 504.

The computing component 500 might also include one or more various forms of information storage mechanism 510, which might include, for example, a media drive 512 and a storage unit interface 520. The media drive 512 might include a drive or other mechanism to support fixed or removable storage media 514. For example, a hard disk drive, a solid-state drive, a magnetic tape drive, an optical drive, a compact disc (CD) or digital video disc (DVD) drive (R or RW), or other removable or fixed media drive might be provided. Storage media 514 might include, for example, a hard disk, an integrated circuit assembly, magnetic tape, cartridge, optical disk, a CD or DVD. Storage media 514 may be any other fixed or removable medium that is read by, written to or accessed by media drive 512. As these examples illustrate, the storage media 514 can include a computer usable storage medium having stored therein computer software or data.

In alternative embodiments, information storage mechanism 510 might include other similar instrumentalities for allowing computer programs or other instructions or data to be loaded into computing component 500. Such instrumentalities might include, for example, a fixed or removable storage unit 522 and an interface 520. Examples of such storage units 522 and interfaces 520 can include a program cartridge and cartridge interface, a removable memory (for example, a flash memory or other removable memory component) and memory slot. Other examples may include a PCMCIA slot and card, and other fixed or removable storage units 522 and interfaces 520 that allow software and data to be transferred from storage unit 522 to computing component 500.

Computing component 500 might also include a communication interface 524. Communications interface 524 might be used to allow software and data to be transferred between computing component 500 and external devices. Examples of communications interface 524 might include a modem or soft modem, a network interface (such as Ethernet, network interface card, IEEE 802.XX or another interface). Other examples include a communications port (such as for example, a USB port, IR port, RS232 port Bluetooth® interface, or other port), or another communications interface. Software/data transferred via communications interface 524 may be carried on signals, which can be electronic, electromagnetic (which includes optical) or other signals capable of being exchanged by a given communications interface 524. These signals might be provided to communications interface 524 via a channel 528. Channel 528 might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to transitory or non-transitory media. Such media may be, e.g., memory 508, storage unit 520, media 514, and channel 528. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing component 500 to perform features or functions of the present application as discussed herein.

It should be understood that the various features, aspects and functionality described in one or more of the individual embodiments are not limited in their applicability to the particular embodiment with which they are described. Instead, they can be applied, alone or in various combinations, to one or more other embodiments, whether or not such embodiments are described and whether or not such features are presented as being a part of a described embodiment. Thus, the breadth and scope of the present application should not be limited by any of the above-described exemplary embodiments.

Terms and phrases used in this document, and variations thereof, unless otherwise expressly stated, should be construed as open ended as opposed to limiting. As examples of the foregoing, the term “including” should be read as meaning “including, without limitation” or the like. The term “example” is used to provide exemplary instances of the item in discussion, not an exhaustive or limiting list thereof. The terms “a” or “an” should be read as meaning “at least one,” “one or more” or the like; and adjectives such as “conventional,” “traditional,” “normal,” “standard,” “known.” Terms of similar meaning should not be construed as limiting the item described to a given time period or to an item available as of a given time. Instead, they should be read to encompass conventional, traditional, normal, or standard technologies that may be available or known now or at any time in the future. Where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “component” does not imply that the aspects or functionality described or claimed as part of the component are all configured in a common package. Indeed, any or all of the various aspects of a component, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A computer-implemented method for estimating depth uncertainty at a well location, the method comprising:
receiving, at a computer processor, mistie data from a plurality of wells in a geographic region;
based on the mistie data, determining a plurality of factors impacting depth uncertainty for each of the plurality of wells;
training one or more machine learning models with the plurality of factors to calculate depth uncertainty for each of the plurality of wells; and
for a new well in the geographic region, applying the trained one or more machine learning models to generate one or more graphical representations of depth uncertainty for the new well.

2. The method of claim 1, wherein a factor of the plurality of factors comprises a total depth below mudline.

3. The method of claim 1, wherein a factor of the plurality of factors comprises well types.

4. The method of claim 1, wherein a factor of the plurality of factors comprises seismic types.

5. The method of claim 1, wherein a factor of the plurality of factors comprises a number of wells in the geographic region.

6. The method of claim 1, wherein a factor of the plurality of factors comprises a distance from a nearest well.

7. The method of claim 1, wherein the one or more graphical representations of depth uncertainty comprises a geographic heat map of depth uncertainty values for the new well.

8. The method of claim 1, further comprising generating a table of numerical values for each factor of the plurality of factors for each of the plurality of wells.

9. A system for estimating depth uncertainty for a well, comprising:
a processor;
a memory encoded with instructions, which, when executed by the processor, causes the processor to:
receive mistie data for a plurality of wells in a geographic region;
based on the mistie data, determine a plurality of factors impacting depth uncertainty for each of the plurality of wells;
train a machine learning model with the plurality of factors to calculate depth uncertainty for each of the plurality of wells; and
for a new well in the geographic region, apply the trained machine learning model to generate a heat map representation of depth uncertainty for the new well.

10. The system of claim 9, wherein a factor of the plurality of factors comprises a total depth below mudline.

11. The system of claim 9, wherein a factor of the plurality of factors comprises well types.

12. The system of claim 9, wherein a factor of the plurality of factors comprises seismic types.

13. The system of claim 9, wherein a factor of the plurality of factors comprises a number of wells in the geographic region.

14. The system of claim 9, wherein a factor of the plurality of factors comprises distance from a nearest well.

15. A non-transitory machine-readable storage medium encoded with instructions, which, when executed by a processor, causes the processor to:
receive mistie data for a plurality of wells in a geographic region;
based on the mistie data, determine a plurality of factors impacting depth uncertainty for each of the plurality of wells;
train a machine learning model with each of the plurality of factors to calculate depth uncertainty for each of the plurality of wells; and
for a new well in the geographic region, apply the trained machine learning model to generate a table of numerical values for each factor of the plurality of factors for each of the plurality of wells illustrating depth uncertainty for each of the plurality of wells.

16. The non-transitory machine-readable storage medium of claim 15, wherein a factor of the plurality of factors comprises a total depth below mudline.

17. The non-transitory machine-readable storage medium of claim 15, wherein a factor of the plurality of factors comprises well types.

18. The non-transitory machine-readable storage medium of claim 15, wherein a factor of the plurality of factors comprises seismic types.

19. The non-transitory machine-readable storage medium of claim 15, wherein a factor of the plurality of factors comprises a number of wells in the geographic region.

20. The non-transitory machine-readable storage medium of claim 15, wherein a factor of the plurality of factors comprises a distance from a nearest well.
